(19) United States
(12) Patent Application Publication
(10) Pub. No.: US 2025/0259929 A1
(43) Pub. Date: Aug. 14, 2025

(54) SEMICONDUCTOR DEVICE AND METHOD OF MANUFACTURING THE SAME

(71) Applicant: Infineon Technologies AG, Neubiberg (DE)

(72) Inventors: Scott David Wallace, Moritzburg (DE); Andreas Meiser, Sauerlach (DE); Stefan Beyer, Villach (AT); Detlef Weber, Ottendorf-Okrilla (DE)

(21) Appl. No.: 19/048,069

(22) Filed: Feb. 7, 2025

(30) Foreign Application Priority Data
Feb. 8, 2024 (DE) 102024201147.9

(51) Int. Cl. H01L 23/528; H01L 23/532; H10D 64/00; H10D 64/27; H10D 84/01; H10D 84/83

(52) U.S. Cl. CPC H01L 23/5286; H01L 23/53257; H10D 84/0149; H10D 84/016; H10D 84/839; H10D 64/117; H10D 64/513

(57) ABSTRACT

The present application relates to a semiconductor device that includes: a device structure in a semiconductor body, with a first load terminal at a first side of the semiconductor body; a lower insulating layer on the first side of the semiconductor body; a conductor line in a lowermost metallization layer on the first side of the semiconductor body; and a load pad in an uppermost metallization layer on the first side of the semiconductor body. The uppermost metallization layer includes a copper layer and the lowermost metallization layer includes a tungsten layer. The conductor line is arranged in a trench in the lower insulating layer.

### TECHNICAL FIELD

The present disclosure relates to a semiconductor device and to a method of manufacturing the same.

### BACKGROUND

The semiconductor device may have a device structure in a semiconductor body, which may be contacted via a metallization on a first side of the semiconductor body. The metallization can comprise a load pad for a contact formation, for example a source pad in case of a FET. The device structure can have a load terminal at the first side of the semiconductor body, for instance a source region of the FET. It may also comprise a control terminal at the first side of the semiconductor body, e.g. a gate electrode.

### SUMMARY

Examples of the present application are directed at a semiconductor device.

In an embodiment, the semiconductor device comprises a lower insulating layer on the first side of the semiconductor body, a conductor line in a lowermost metallization layer on the first side of the semiconductor body, and a load pad in an uppermost metallization layer on the first side of the semiconductor body. The lowermost metallization layer comprises a tungsten layer and the uppermost metallization layer comprises a copper layer, for example for a contact formation by wire bonding and/or soldering. The conductor line formed in the lowermost metallization layer is arranged in an opening or trench in the lower insulating layer, e.g. is embedded into the lower insulating layer.

The conductor line may improve a lateral distribution of a control signal, for example gate signal, and avoid an interruption of the load pad. Embedding the conductor line into the lower insulating layer may reduce a topology, for instance of a passivation layer and/or in an imide layer on the uppermost metallization layer (see in detail below). A reduced topology can for example have advantages in subsequent handling steps, e.g. mounting and/or contacting steps.

Embodiments and features are provided throughout the disclosure which relates to apparatus and device aspects, but also to method and use aspects. If for instance a device manufactured in a certain way is described, this is also a disclosure of a respective manufacturing process, and vice versa. In general words, an approach of this application is to provide a semiconductor device which has a lowermost metallization layer in addition to an uppermost metallization layer above, wherein a conductor line formed in the lowermost metallization layer, for example for a control/gate signal amplification, is embedded into a lower insulating layer.

Though being different layers, e.g. deposited in subsequent process steps, the embedded conductor line or lowermost metallization layer may be arranged on the same vertical height as the lower insulating layer, e.g. in a common lateral plane. A respective layer may be structured, e.g. the conductor line being formed in the lowermost metallization layer and the trench being formed in the lower insulating layer, so that at least where the conductor line is embedded into the lower insulating layer, the lowermost metallization layer and the lower insulating layer may be arranged on the same vertical height. In other words, a respective layer denotes a material layer that may cover the first side of the semiconductor only partly, so that different layers can be arranged in a common horizontal plane (vice versa, the term layer shall not denote a horizontal plane covering the first side of the semiconductor body completely). To sum up, the lowermost metallization layer and the lower insulating layer, which are deposited in different process steps, differ in their respective material and not necessarily in their vertical position on or vertical distance from the first side of the semiconductor body.

The embedded conductor line may be enclosed laterally in the lower insulating layer, for instance with respect to a transverse direction which lies perpendicular to a length direction of the conductor line. The conductor line may for instance extend continuously, e.g. without an interruption, from below a control pad aside the load pad to below the load pad, for example from below a gate pad to below the source pad. Its length direction can for instance lie parallel to the control or gate electrode arranged below, e.g. to improve the control signal distribution along the gate electrode.

Generally, in this disclosure, “below” and “above” refer to the vertical direction which lies perpendicular to the lateral directions, wherein “below” means closer to the semiconductor body and “above” at a greater distance therefrom (which applies in a stack on the semiconductor body). Vertically, the trench in the lower insulating layer may intersect the lower insulating layer completely, e.g. extend between an upper end and a lower end of the lower insulating layer. The lower insulating layer may for instance be doped or undoped silicon oxide.

The lowermost metallization layer, in which the conductor line is formed, can comprise a tungsten layer which may be the sole layer of the lowermost metallization layer or a sublayer in a layer stack. The tungsten layer may have advantages in terms of corrosion or mechanical stiffness, for instance in comparison to an aluminum layer. The lowermost metallization layer may comprise a metallic barrier layer or layers below the tungsten layer, for instance at least one of a titanium, titanium nitride or titanium tungsten layer. The barrier layer may have a thickness of at least 5 nm and not more than 50 nm, 30 nm or 15 nm and/or the tungsten layer may have a thickness of at least 100 nm or at least 130 nm, possible upper limits being for instance not more than 300 nm or 200 nm.

The uppermost metallization layer, in which the load pad and for instance a control pad may be formed, can for instance have a thickness of at least 3 μm, 4 μm or 5 μm (possible upper limits being for example 20 μm or 15 μm). It may comprise the copper layer, which may be the sole layer of the uppermost metallization layer or a sublayer in a layer stack. The uppermost metallization layer can additionally comprise a metallic barrier layer and/or a metallic adhesion layer below the copper layer, see in further detail below.

The semiconductor device may be a power device, e.g. having a breakdown voltage of at least 10 V, 20 V or 30 V, with possible upper limits of for instance not more than 800 V, 600 V, 400 V or 200 V. For instance in case of a FET, it can have a source region and a drain region, as well as a body region. The source region may be the first load terminal at the first side of the semiconductor body, wherein the drain region (second load terminal) can be arranged at the first side as well or at a vertically opposite second side of the semiconductor body. Independently of these details, the load pad formed in the uppermost metallization layer may be connected to the first load terminal of the device structure, it may for instance be a source plate connected to the source region.

In an embodiment, the embedded conductor line lies flush in the lower insulating layer. In other words, an upper end of the conductor line and an upper end of the lower insulating layer are arranged on the same vertical height. After filling the trench with the metal material of the lower metallization layer, a planarization step may be applied, wherein an upper side of the conductor line then lies, for example, in one plane with an upper side of lower insulating layer. As discussed above, the layers differ in their respective material and, due to the respective structuring (conductor line versus trench), in their lateral extension and shape, but they may be arranged on the same vertical position (the conductor line being embedded into the lower insulating layer).

In an embodiment, the device comprises an upper insulating layer on the lower insulating layer. With respect to the vertical direction, the upper insulating layer may lie adjacent to the lower insulating layer, e.g. be deposited directly onto the lower insulating layer. The upper insulating layer is arranged below the uppermost metallization layer (e.g. apart from openings/interconnects), for instance below the load pad formed in the uppermost metallization layer.

In an embodiment, the upper insulating layer is made of a harder material than the lower insulating layer. The upper insulating layer may serve as a hard passivation of the device, for instance to protect or seal the device structure, e.g. against ion diffusion. In other words, the hard passivation may be integrated below the load pad/uppermost metallization layer. The upper insulating layer may be made of silicon nitride, for example in combination with a lower insulating layer made of silicon oxide.

In an embodiment, the upper insulating layer is intersected locally by a vertical load interconnect which provides an electrical connection between the load pad and the first load terminal of the device structure, e.g. between the source pad and the source region. The vertical load interconnect may be formed in the uppermost metallization layer, e.g. be filled by the layer or sublayers (layer stack) of the uppermost metallization system. In other words, the same metallic barrier layer and/or metallic adhesion layer and/or copper layer deposited for the load pad may fill or form the vertical load interconnect. This applies also to a vertical control interconnect which may connect a control pad, e.g. gate pad, aside the load pad in the uppermost metallization layer to the conductor line below.

In an embodiment, a lower load interconnect intersects the lower insulation layer and connects the first load pad to the first load terminal of the device structure. In detail, the lower load interconnect can be connected vertically between the vertical load interconnect and the first load terminal. The lower load interconnect may be made of the same metallic material as the conductor line, e.g. comprise a tungsten layer and optionally a barrier layer below. In other words, the lower load interconnect and the conductor line may be made in the same process step or steps.

In an embodiment, the conductor line below the load pad is completely covered by the upper insulating layer. Alternatively or in addition, the conductor line laterally between the load pad and a control pad, e.g. gate pad, may be completely covered by the upper insulating layer. Where the conductor line is completely covered, the upper insulating layer is, for example, not interrupted above the conductor line. Laterally aside, it may be interrupted, for example where a vertical load interconnect is formed.

In an embodiment, the lowermost metallization layer and the uppermost metallization layer are the only metallization layers on the first side of the semiconductor body. Each of these two metallization layers may comprise different metallic sublayers, but no additional metal layer isolated from the uppermost and the lowermost metallization layer shall be arranged in between. In other words, the frontside metallization consists of two metallization layers, namely the lowermost and the uppermost metallization layer. The vertical load interconnect may connect directly to the lower load interconnect and/or the vertical control interconnect may connect directly to the conductor line and/or a lower load interconnect may connect directly to the load terminal and/or the conductor line may connect directly to the control electrode, e.g. gate electrode. Irrespective of this, a metallization may be provided at the second side of the semiconductor body, namely a backside metallization.

As mentioned, the uppermost metallization layer may comprise a barrier layer below the copper layer, wherein the barrier layer may, among other elements, for instance comprise titanium nitride and/or tungsten (for example TiN layer+W layer). In an embodiment, the barrier layer is laterally set back inwards, a lateral edge of the barrier layer being covered by the copper layer. Seen for example in a vertical cross-section perpendicular to the lateral edge of the barrier layer, a lateral spacing between this lateral edge of the barrier layer and a lateral edge of the copper layer may be at least 1 μm or 2 μm (possible upper limits being for example 25 μm, 15 μm or 10 μm). If an adhesion layer is provided between the barrier layer and the copper layer, the barrier layer may also be laterally set back inwards with respect to the adhesion layer. In other words, a respective lateral edge of the adhesion layer and of the copper layer may be arranged on basically the same lateral position, the barrier layer set back inwards and enclosed laterally by the adhesion and/or copper layer. Considering the upper metallization layer as a whole, this may for instance allow for a defined lateral edge.

In an embodiment, the device structure has a second load terminal at a second side of the semiconductor body. This may for instance be a drain region (see above), the device structure having its source region at the first side and its drain region at the second side of the semiconductor body. In between, a body region comprising a channel region may be arranged, to which the gate electrode capacitively couples via a gate dielectric. The source and drain region may be made of a first doping type and the body region may be made of a second doping type, wherein the first type is for instance n-type and the second type is p-type.

In an embodiment, the device or device structure comprises a gate electrode in a trench which extends from the first side into the semiconductor body and has an elongated lateral extension. Alternatively or in addition, the device or device structure may comprise a field electrode in a trench which extends from the first side into the semiconductor body and has an elongated lateral extension. Separate trenches may be provided for the gate and field electrode, alternatively the gate and field electrode may be arranged in a common trench. Irrespective of this in detail, the field electrode may be arranged aside a drift region of the device structure, e.g. made of the same doping type but with a lower doping concentration compared to the drain region.

In an embodiment, the conductor line is stacked above the gate electrode, e.g. extends in parallel to the elongated trench with the gate electrode. The gate electrode and conductor line may be made of different materials, for example the gate electrode of polysilicon. The conductor line above may be formed directly adjacent to the gate electrode, e.g. to improve the lateral gate signal distribution along the gate electrode.

In an embodiment, a method of manufacturing a semiconductor device is provided. It may comprise: forming the lower insulating layer on the first side of the semiconductor body; etching the trench into the lower insulating layer; filling the trench with a tungsten material. Regarding possible details of the device, reference is made to the disclosure as a whole.

Prior to the tungsten material deposition, a barrier layer may be formed, e.g. covering a bottom of the trench. The tungsten material may be deposited in excess, excess tungsten material extending for instance above an upper side of the lower insulating layer and covering the latter. The excess tungsten material, e.g. together with the barrier layer lying on the surface of the lower insulating layer, may be removed by planarization, for example by a chemical mechanical polishing (CMP). As a result, the conductor line may lie flush in the lower insulating layer.

In an embodiment, the conductor line and a lower load interconnect, which may connect the load pad to the first load terminal later on, are made simultaneously. With the tungsten material deposition for the conductor line, possibly in combination with a barrier layer deposition before, the conductor line and also the lower load interconnect may be formed.

### BRIEF DESCRIPTION OF THE DRAWINGS

Below, the semiconductor device and the method of manufacturing the same are explained in further detail by exemplary embodiments. The individual features can also be relevant for the disclosure in a different combination.

FIG. 1 shows a semiconductor device in a cross-sectional view;

FIG. 2 shows a portion of the device of FIG. 1 in a sectional plane perpendicular to the drawing plane of FIG. 1;

FIG. 3 shows further details of the semiconductor device in a cross-sectional view;

FIG. 4 shows a detailed view of a lateral edge of an uppermost metallization layer with a copper layer;

FIG. 5 summarizes some manufacturing steps in a flow diagram;

FIGS. 6 a-f illustrate some manufacturing steps in further detail.

### DETAILED DESCRIPTION

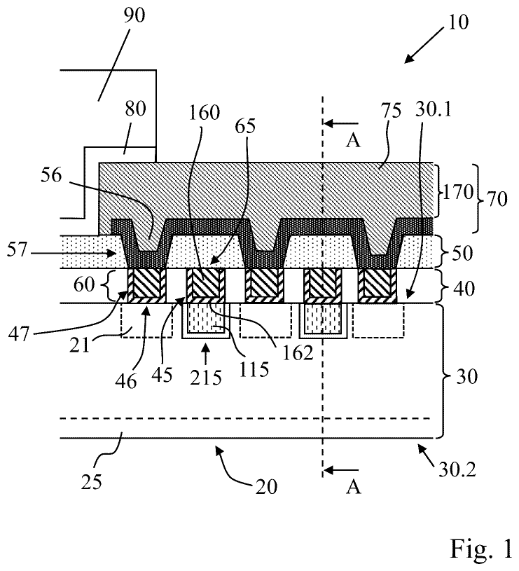

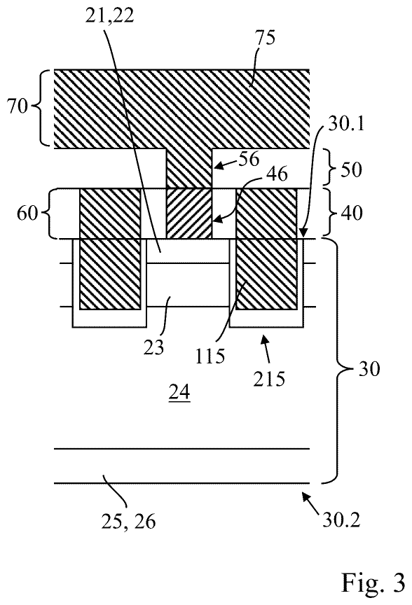

FIG. 1 shows a semiconductor device 10 in a cross-sectional view. It comprises a device structure 20 in a semiconductor body 30, the device structure 20 having a first load terminal 21 at a first side 30.1 and a second load terminal 25 at a second side 30.2 of the semiconductor body 30. The load terminals 21, 25 are shown only schematically in FIG. 1, for further details of the device structure 20 reference is made to FIG. 3.

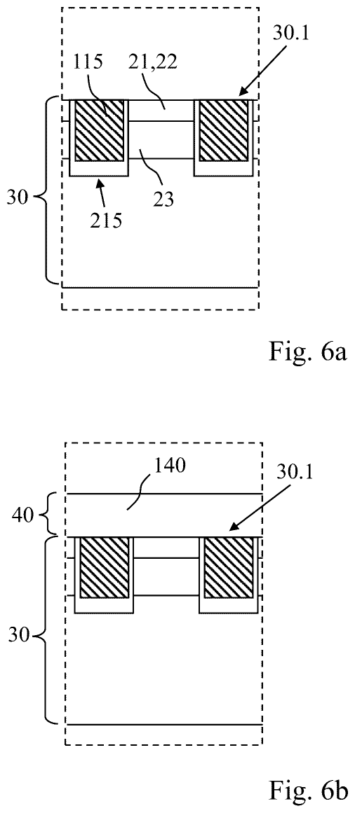

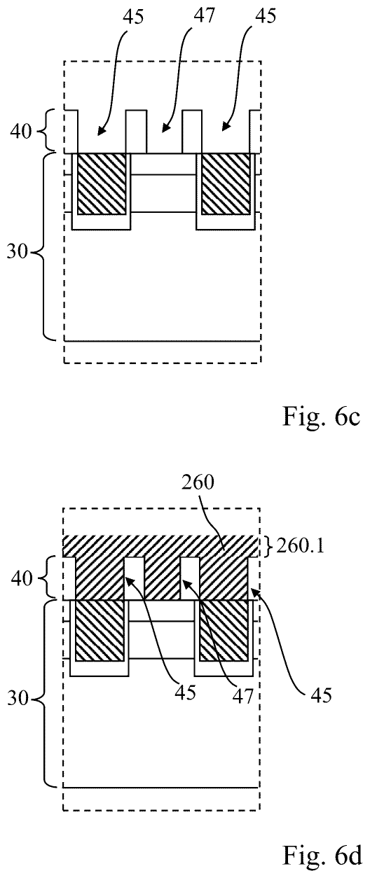

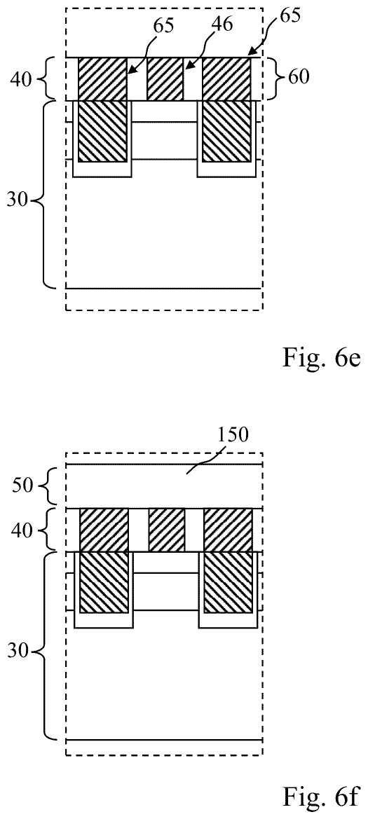

On the first side 30.1 of the semiconductor body 30, a lower insulating layer 40 is arranged, which is made of silicon oxide in the example shown. A conductor line 65 is embedded into the lower insulating layer 40, namely is arranged in a trench 45 in the lower insulating layer 40. The conductor line 65 lies flush in the lower insulating layer 40, which may be obtained in a planarization step (see FIGS. 6d/e in detail). The conductor line 65 is formed in a lowermost metallization layer 60 which is at least locally embedded into the lower insulating layer 40 (arranged on the same vertical position, as discussed above). The lowermost metallization layer 60 comprises a tungsten layer 160 and a barrier layer 162 below, for example a titanium nitride layer (or a TiN+W layer stack). In the example shown, the barrier layer 162 has a thickness of around 10 nm and the tungsten layer 160 has a thickness of around 150 nm.

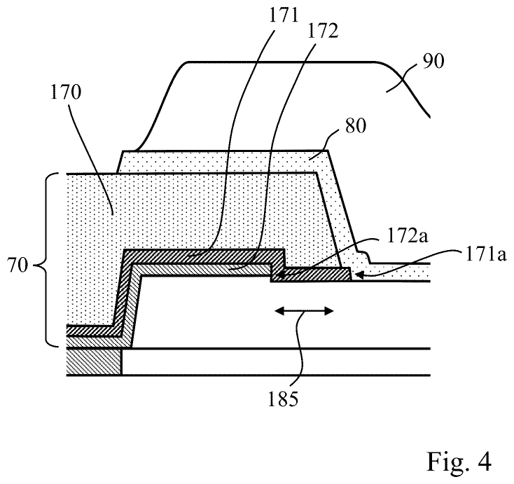

An upper insulating layer 50 is disposed on the lower insulating layer 40 and covers the conductor line 65. The upper insulating layer 50 is made of a harder material compared to the lower insulating layer 40, which is silicon nitride in this example. On the upper insulating layer 50, an uppermost metallization layer 70 is arranged. It comprises a copper layer 170 with a thickness of around 7 μm in this example. Below, further layers are arranged (not referenced here), see FIG. 4 in further detail. In the uppermost metallization layer 70, a load pad 75 is formed, which may be a source pad. The load pad 75 can be covered by a passivation layer 80 and/or an imide layer 90, a central portion of load pad 75 left open for a contact formation in backend of line processing.

A vertical load interconnect 56 intersects the upper insulating layer 50 and connects the load pad 75 to the first load terminal 21. A respective opening 57 in the upper insulating layer 50 is filled with the uppermost metallization layer 70, which forms the vertical load interconnect 56. Below, an opening 47 in the lower insulating layer 40 is filled with the stack of the lowermost metallization layer 60, namely with the barrier layer 162 and the tungsten layer 160.

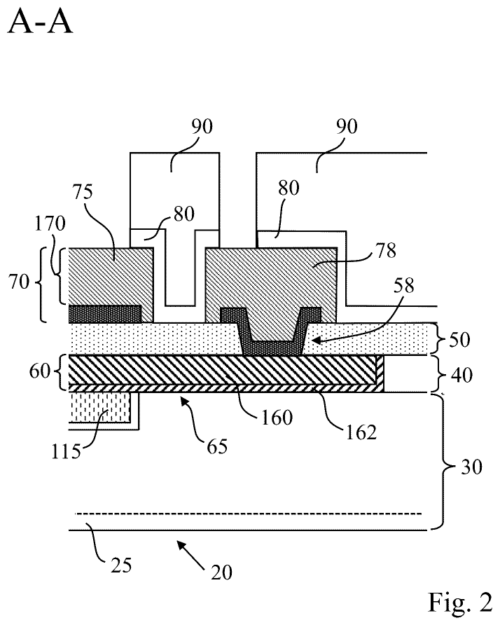

Below the conductor line 65, a gate electrode 115 is arranged in a trench 215. Perpendicular to the drawing plane, it has an elongated lateral extension, the conductor line 65 extending in parallel to it. This is illustrated in further detail in FIG. 2 which shows a cross-section perpendicular to the drawing plane of FIG. 1 (see A-A for illustration). In the active area of the device structure 20, e.g. below the load pad 75, the conductor line 65 is stacked on the gate electrode 115 and extends in parallel. The gate electrode 115 ends below the load pad 75 and the conductor line 65 forms an electrical connection to a control pad 78 aside the load pad 75.

Below the load pad 75 and in between the load pad 75 and the control pad 78, the conductor line 65 is covered by the upper insulating layer 50. Via a vertical control interconnect 58 below the control pad 78, the conductor line 65 is connected to the control pad 78.

FIG. 3 illustrates the device structure 20 in further detail. Generally, in this disclosure, the like reference numerals indicate the like elements or elements having the like function and reference is made to the description of the other figures as well. In case of the FET illustrated in FIG. 3, the first load terminal 21 is a source region 22 at the first side 30.1 of the semiconductor body 30. The second load terminal 25 at the vertically opposite second side 30.2 is a drain region 26, wherein a body region 23 is arranged in between, optionally in combination with a drift region 24. In the example shown, the source region 22, drift region 24 and drain region 25 are n-doped, the body region 23 being p-doped.

The lowermost and uppermost metallization layer 60, 70, and respective interconnects, are only shown schematically in FIG. 3. The lower load interconnect 46 and vertical load interconnect 56 connect the load pad 75, e.g. source plate, to the source region 22. The like interconnect structure may be provided for connecting the load pad 75 to a field electrode in a trench aside the drift region (not shown here).

FIG. 4 illustrates the uppermost metallization layer 70 in detail. In addition to the copper layer 170, it comprises an adhesion layer 171 and a barrier layer 172 below. The adhesion layer 171 may be a copper layer as well, for example sputter deposited in comparison to the copper layer 170 obtained from bath deposition. The barrier layer 172 may be a titanium nitride layer. With respect to the copper layer 170 and the adhesion layer 171, the barrier layer 172 is laterally set back inwards. A lateral edge 172a of the barrier layer 172 may be covered, e.g. laterally and vertically, in the stack. A vertical distance 185 between the lateral edge 172a of the barrier layer 172 and a lateral edge 171a of the adhesion layer 171 and/or a lateral edge 170a of the copper layer 170 is around 10 μm in this example.

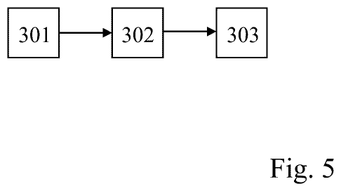

FIG. 5 summarizes some manufacturing steps in a flow diagram. The method may comprise forming 301 the lower insulating layer on the first side of the semiconductor body, etching 302 the trench into the lower insulating layer and filling 303 the trench with tungsten material.

FIGS. 6a-f illustrate some manufacturing steps in further detail. FIG. 6a shows the semiconductor body 30, wherein the device structure 20 has been formed already (e.g. doped regions and gate trenches). Then, the lower insulating layer 40 is formed on the first side 30.1 of the semiconductor body 30 by depositing silicon oxide 140, see FIG. 6b. In the step shown in FIG. 6c, the trenches 45 (for the conductor lines) and opening 47 (for the lower load interconnect) have been etched into the lower insulating layer 40. For this etch step, a structured mask may be provided on the lower insulating layer 40, which is not shown in detail here.

FIG. 6d shows the structure after a deposition of the lowermost metallization layers 60, wherein only the tungsten material 260 is shown (not the thin barrier layer below). The tungsten material 260 fills the trenches 45 and opening 47, wherein excess tungsten material 260.1 covers the upper side of the lower insulating layer 40.

FIG. 6e shows the structure after a planarization, namely after a removal of the excess tungsten material from the upper side of the lower insulating layer 40 by chemical mechanical polishing. Likewise, the lower metallization layer 60, e.g. conductor lines 65 and lower load interconnect 46 are embedded into the lower insulating layer 40. Subsequently, the upper insulating layer 50 may be formed by deposition of silicon nitride 150, see FIG. 6f. In a subsequent step not shown here, the silicon nitride 150 may be opened locally to form the contacts to the uppermost metallization layer later on, see FIGS. 1-3 for comparison.

Embodiments and features of the present application can be summarized in the form of the following examples:

Example 1. A semiconductor device (10), comprising: a device structure (20) in a semiconductor body (30), with a first load terminal (21) at a first side (30.1) of the semiconductor body (30); a lower insulating layer (40) on the first side (30.1) of the semiconductor body (30); a conductor line (65) in a lowermost metallization layer (60) on the first side (30.1) of the semiconductor body (30); a load pad (75) in an uppermost metallization layer (70) on the first side (30.1) of the semiconductor body (30), the uppermost metallization layer comprising a copper layer (170) and the lowermost metallization layer (60) comprising a tungsten layer (160), wherein the conductor line (65) is arranged in a trench (45) in the lower insulating layer (40).

Example 2. The semiconductor device (10) of example 1, wherein the conductor line (65) lies flush in the lower insulating layer (40).

Example 3. The semiconductor device (10) of example 1 or 2, comprising: an upper insulating layer (50) on the lower insulating layer (40).

Example 4. The semiconductor device (10) of example 3, the upper insulating layer (50) made of a harder material than the lower insulating layer (40).

Example 5. The semiconductor device (10) of example 3 or 4, the upper insulating layer (50) intersected locally by a vertical load interconnect (56) providing an electrical connection between the load pad (75) and the first load terminal (21), the vertical load interconnect (56) formed in the uppermost metallization layer (70).

Example 6. The semiconductor device (10) of example 5, the vertical load interconnect (56) connected to the first load terminal (21) via a lower load interconnect (46), wherein the lower load interconnect (46) intersects the lower insulation layer (40) and is made of the same tungsten layer (160) like the conductor line (65).

Example 7. The semiconductor device (10) of any one of examples 3 to 6, wherein the conductor line (65) below the load pad (75) and/or laterally between the load pad (75) and a control pad (78) is completely covered by the upper insulating layer (50).

Example 8. The semiconductor device (10) of any one of the preceding examples, wherein the lowermost metallization layer (60) and the uppermost metallization layer (70) are the only metallization layers on the first side (30.1) of the semiconductor body (30).

Example 9. The semiconductor device (10) of any one of the preceding examples, the uppermost metallization layer comprising a barrier layer (172) below the copper layer (170), wherein the barrier layer (172) is laterally set back inwards, a lateral edge (172a) of the barrier layer (172) being covered by the copper layer (170).

Example 10. The semiconductor device (10) of any one of the preceding examples, the device structure (20) having a second load terminal (25) at a second side (30.2) of the semiconductor body (30), vertically opposite to the first side (30.1).

Example 11. The semiconductor device (10) of any one of the preceding examples, the device structure (20) having a gate electrode (115) and/or a field electrode disposed in a trench (215) which extends from the first side (30.1) into the semiconductor body (30) and has an elongated lateral extension.

Example 12. The semiconductor device (10) of example 11, wherein the conductor line (65) extends in parallel to the trench (215) and to the gate electrode (115) disposed in the trench (215), the conductor line (65) stacked above the gate electrode (115).

Example 13. A method of manufacturing a semiconductor device (10), comprising:
i.) forming (301) a lower insulating layer (40) on a first side (30.1) of a semiconductor body (30);
ii.) etching (302) a trench (45) into the lower insulating layer (40);
iii.) filling (303) the trench (45) with a tungsten material (260).

Example 14. The method of example 13 for manufacturing the semiconductor device (10) of example 2, wherein in step iii.) the tungsten material (260) is deposited in excess, with excess tungsten material (260.1) being subsequently removed by planarization.

Example 15. The method of example 13 or 14 for manufacturing the semiconductor device (10) of example 6, wherein the lower load interconnect (46) and the conductor line (65) are made simultaneously.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore. it is intended that this invention be limited only by the claims and the equivalents thereof.

What is claimed is:

1. A semiconductor device, comprising:
a device structure in a semiconductor body, with a first load terminal at a first side of the semiconductor body;
a lower insulating layer on the first side of the semiconductor body;
a conductor line in a lowermost metallization layer on the first side of the semiconductor body; and
a load pad in an uppermost metallization layer on the first side of the semiconductor body,
wherein the uppermost metallization layer comprises a copper layer and the lowermost metallization layer comprises a tungsten layer,
wherein the conductor line is arranged in a trench in the lower insulating layer.

2. The semiconductor device of claim 1, wherein the conductor line lies flush in the lower insulating layer.

3. The semiconductor device of claim 1, further comprising:
an upper insulating layer on the lower insulating layer.

4. The semiconductor device of claim 3, wherein the upper insulating layer is made of a harder material than the lower insulating layer.

5. The semiconductor device of claim 3, wherein the upper insulating layer is intersected locally by a vertical load interconnect providing an electrical connection between the load pad and the first load terminal, and wherein the vertical load interconnect is formed in the uppermost metallization layer.

6. The semiconductor device of claim 5, wherein the vertical load interconnect is connected to the first load terminal via a lower load interconnect, and wherein the lower load interconnect intersects the lower insulation layer and is made of a same tungsten layer as the conductor line.

7. The semiconductor device of claim 3, wherein below the load pad and/or laterally between the load pad and a control pad, the conductor line is completely covered by the upper insulating layer.

8. The semiconductor device of claim 1, wherein the lowermost metallization layer and the uppermost metallization layer are the only metallization layers on the first side of the semiconductor body.

9. The semiconductor device of claim 1, wherein the uppermost metallization layer comprises a barrier layer below the copper layer, wherein the barrier layer is laterally set back inwards, and wherein a lateral edge of the barrier layer is covered by the copper layer.

10. The semiconductor device of claim 1, wherein the device structure has a second load terminal at a second side of the semiconductor body vertically opposite to the first side.

11. The semiconductor device of claim 1, wherein the device structure has a gate electrode and/or a field electrode disposed in a trench which extends from the first side into the semiconductor body and has an elongated lateral extension.

12. The semiconductor device of claim 11, wherein the conductor line extends in parallel to the trench and to the gate electrode disposed in the trench, and wherein the conductor line is stacked above the gate electrode.

13. A method of manufacturing a semiconductor device, the method comprising:
forming a lower insulating layer on a first side of a semiconductor body;
etching a trench into the lower insulating layer; and
filling the trench with a tungsten material.

14. The method of claim 13, wherein during the filling of the trench with the tungsten material, the tungsten material is deposited in excess, with the excess tungsten material being subsequently removed by planarization.

15. The method of claim 14, wherein the semiconductor device includes a conductor line in a lowermost metallization layer on the first side of the semiconductor body, wherein the conductor line is arranged in the trench in the lower insulating layer, and wherein the conductor line lies flush in the lower insulating layer after the planarization.

16. The method of claim 13, wherein the semiconductor device includes a first load terminal at the first side of the semiconductor body, a conductor line in a lowermost metallization layer on the first side of the semiconductor body, and a load pad in an uppermost metallization layer on the first side of the semiconductor body, the method further comprising:
forming an upper insulating layer on the lower insulating layer.

17. The method of claim 16, wherein the upper insulating layer is intersected locally by a vertical load interconnect providing an electrical connection between the load pad and the first load terminal, and wherein the vertical load interconnect is formed in the uppermost metallization layer.

18. The method of claim 17, wherein the vertical load interconnect is connected to the first load terminal via a lower load interconnect, and wherein the lower load interconnect intersects the lower insulation layer and is made of a same tungsten layer as the conductor line.

19. The method of claim 18, wherein the lower load interconnect and the conductor line are made simultaneously.
